(19) United States
(12) Patent Application Publication
(10) Pub. No.: US 2009/0087567 A1
(43) Pub. Date: Apr. 2, 2009

(54) METHOD OF FABRICATING ONE-DIMENSIONAL METALLIC NANOSTRUCTURE

(75) Inventors: Shyan-kay Jou, Taipei City (TW); Dong-Yu Yeh, Taipei County (TW)

Correspondence Address: J C PATENTS, INC., 4 VENTURE, SUITE 250, IRVINE, CA, 92618, US

(73) Assignee: National Taiwan University of Science and Technology, Taipei City (TW)

(21) Appl. No.: 11/939,341

(22) Filed: Nov. 13, 2007

(30) Foreign Application Priority Data
Oct. 2, 2007 (TW) 96136909

(51) Int. Cl. B05D 3/10; C23C 14/34

(52) U.S. Cl. 427/344; 204/192.1; 427/343; 977/762

(57) ABSTRACT

A method of fabricating one-dimensional metallic nanostructure is provided. First, a mixing layer including a first oxide and a second oxide is provided. The first oxide is a metallic oxide, and the first oxide and the second oxide are immiscible. Next, a reducing gas is introduced and a thermal process is performed on the mixing layer so as to reduce the metal of the first oxide to form one-dimensional metallic nanostructure.

### CROSS-REFERENCE TO RELATED APPLICATION

This application claims the priority benefit of Taiwan application serial no. 96136909, filed on Oct. 2, 2007. The entirety of the above-mentioned patent application is hereby incorporated by reference herein and made a part of this specification.

### BACKGROUND OF THE INVENTION

1. Field of the Invention

The present invention relates to a method of fabricating a nanostructure, and more particularly to a method of fabricating a one-dimensional metallic nanostructure.

2. Description of Related Art

Along with the miniaturization requirement for various products, science and technology have been developed from the micron-era to the so-called nano-era. Nano-materials have a variety of types, including metallic nano-materials, semiconductor nano-materials, nanostructured ceramics, and nano polymer materials, and may have a zero-dimensional structure, one-dimensional structure, two-dimensional structure, or other structures. The processing methods and researches of the one-dimensional metallic nanostructures are most challenging, and are also the most potential ones.

Physical, mechanical, and chemical properties of a material are greatly changed when the size is reduced into the nano-scaling, as compared with a bulk material. Therefore, in addition to changing the composition of the material to obtain required properties of different materials, basic characteristics such as the melt point, color, optical, electrical, and magnetic properties of the same material may also be further controlled by controlling the size and shape of this material. Based on this feature, high-performance products or techniques that cannot be achieved in the past may be realized in the field of nano science and technology.

Currently, the methods of fabricating the one-dimensional metallic nanostructure include nano-template, step deposition, liquid phase nucleation, and so on. Natural or synthetic nano-porus materials are adopted in conjunction with various metal deposition techniques to form this nanostructure. However, a multi-stage growth must be employed in the above methods for fabricating the one-dimensional metallic nanostructures, and the crystallinity of the fabricated material is unsatisfactory. Therefore, it is an important challenge to the existing processes how to control the size uniformity and crystallinity when preparing the one-dimensional metallic nanostructures.

Moreover, techniques related to the metallic nanostructure and the fabricating method thereof has been disclosed in some patents, such as U.S. Pat. No. 6,858,318; US 2007/0089564A1; and JP 2004223693A2. The above documents are all incorporated herein by reference.

### SUMMARY OF THE INVENTION

Accordingly, the present invention is directed to a method of fabricating a one-dimensional metallic nanostructure, so as to form the one-dimensional metallic nanostructure with high crystallinity in an easier manner.

The present invention provides a method of fabricating a one-dimensional metallic nanostructure. First, a mixing layer including a first oxide and a second oxide is formed. The first oxide is a metallic oxide, and the first oxide and the second oxide are immiscible. A reducing gas is introduced and a thermal process is preformed on the mixing layer, so as to reduce a metal of the first oxide and form the one-dimensional metallic nanostructure on a surface of the mixing layer.

In the method of fabricating a one-dimensional metallic nanostructure according to an embodiment of the present invention, the reducing gas is, for example, hydrogen (H₂) or other suitable reducing gases.

In the method of fabricating a one-dimensional metallic nanostructure according to an embodiment of the present invention, a process temperature of the thermal process is between 600° C. and 950° C.

In the method of fabricating a one-dimensional metallic nanostructure according to an embodiment of the present invention, the thermal process is, for example, an annealing process or other suitable thermal processes.

In the method of fabricating a one-dimensional metallic nanostructure according to an embodiment of the present invention, the first oxide is, for example, nickel oxide (NiO), copper oxide (CuO), or other suitable metallic oxides.

In the method of fabricating a one-dimensional metallic nanostructure according to an embodiment of the present invention, the second oxide is, for example, a metallic oxide or a ceramic oxide. The metallic oxide is, for example, zirconium oxide (ZrO₂), yttria-stabilized zirconia (YSZ), cerium oxide doped yttria-stabilized zirconia (CeO₂-doped YSZ), or other suitable metallic oxides, and the ceramic oxide is, for example, silica or other suitable ceramic oxides.

In the method of fabricating a one-dimensional metallic nanostructure according to an embodiment of the present invention, the mixing layer is formed by, for example, a sputtering process, a deposition process, or other suitable methods.

In the method of fabricating a one-dimensional metallic nanostructure according to an embodiment of the present invention, the one-dimensional metallic nanostructure is, for example, one-dimensional nanowires, one-dimensional nanorods, or one-dimensional nanocones.

In the method of the present invention, a reducing gas is used and a thermal process is performed to reduce the metal in an oxide in the oxidized mixing layer, so as to form the one-dimensional metallic nanostructure. Therefore, the method of the present invention is easy and simple compared with the conventional art, and is capable of forming a one-dimensional metallic nanostructure with higher crystallinity.

In order to make the aforementioned and other objects, features and advantages of the present invention comprehensible, preferred embodiments accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to describe the principles of the invention.

FIG. 1 is a flow chart of a method of fabricating a one-dimensional metallic nanostructure according to the present invention.

FIG. 2 is an SEM photograph of an oxide mixing layer (NiO-doped YSZ).

FIG. 3 is an SEM photograph of the mixing layer after going through the annealing process with H₂.

FIG. 4 is an XRD spectrum of the oxide mixing layer (NiO-doped YSZ) and the mixing layer after going through the annealing process with H₂

FIG. 5A is a TEM photograph of the one-dimensional metallic nanostructure obtained after the annealing process with H₂.

FIG. 5B is an enlarged TEM photograph of FIG. 5A with an electron-diffraction spectrum inserted.

### DESCRIPTION OF EMBODIMENTS

The present invention provides a novel and easy direct growth method, for fabricating a one-dimensional metallic nanostructure with a better crystallinity than that of the one-dimensional metallic nanostructure fabricated by the conventional methods.

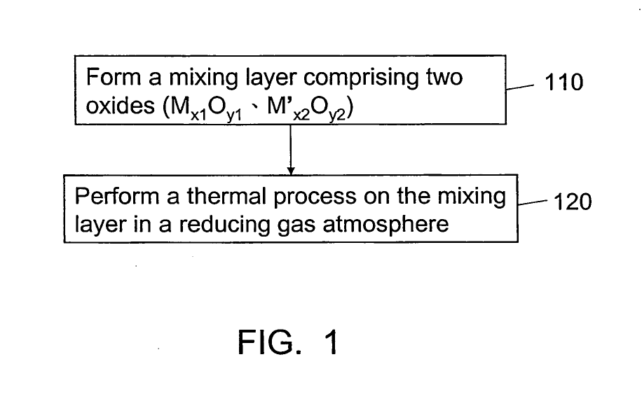

The method of fabricating a one-dimensional metallic nanostructure of the present invention includes the following steps. Referring to FIG. 1, first, a mixing layer including two immiscible oxides is formed (Step 110). In detail, in Step 110, the oxide mixing layer is formed by, for example, a sputtering process or a deposition process. The mixing layer includes a first oxide (with a general formula of Mₓ₁O_{y1}) and a second oxide (with a general formula of M′ₓ₂O_{y2}). Mₓ₁O_{y1} is a metallic oxide, for example, nickel oxide (NiO), copper oxide (CuO) or other suitable metallic oxides. M′ₓ₂O_{y2} is a metallic oxide or a ceramic oxide. The metallic oxide is, for example, zirconium oxide (ZrO₂), yttria-stabilized zirconia (YSZ), cerium oxide doped yttria-stabilized zirconia (CeO₂-doped YSZ), or other suitable metallic oxides, and the ceramic oxide is, for example, silica or other suitable ceramic oxides.

Referring to FIG. 1, next, a thermal process is performed on the mixing layer under a reducing gas atmosphere (Step 120). In detail, in Step 120, the thermal process is performed on the mixing layer by, for example, introducing H₂ or other suitable gases as the reducing gas. The thermal process is, for example, an annealing process or other suitable thermal processes, and has a process temperature between 600° C. and 950° C., and preferably between 800° C. and 900° C. In addition, when introducing the reducing gas, nitrogen (N₂) or inert gases such as helium (He), neon (Ne), argon (Ar), krypton (Kr), xenon (Xe), radon (Rn) may also be added.

When performing the Step 120, the thermal process may lead to the oxides (Mₓ₁O_{y1}, M′ₓ₂O_{y2}) in the mixing layer tending to be separated. Meanwhile, the reducing gas promotes the reduction of metal (M) in the Mₓ₁O_{y1}, so as to precipitate the metal (M) to form a one-dimensional metallic nanostructure on the surface of the mixing layer. The formed one-dimensional metallic nanostructure may be nanowires, nanorods or nanocones.

Hereinafter, several experimental examples are described to illustrate the present invention, instead of limiting the present invention.

### Experimental Examples

### Fabrication of the Oxide Mixing Layer

First, a silicon substrate is provided. Then, Ar and O₂ gases are introduced, so as to generate a plasma bombard sputter target material (Ni and Zr—Y—Ce), form NiO and CeO₂-doped YSZ, and form the oxide mixing layer (NiO-doped YSZ) on the silicon substrate. Herein, the flux of Ar gas is, for example, 10 sccm, and the flux of O₂ gas is, for example, 10 sccm.

Forming One-Dimensional Ni Nanorods.

The formed oxide mixing layer is placed into a furnace device, and H₂ and Ar gases (H₂:Ar=20 vol %:80 vol %) are introduced. Under 800° C., an annealing process is performed on the oxide mixing layer for about 60 minutes. Ni metal in the oxide mixing layer is reduced by H₂, so as to be precipitated on the surface of the mixing layer, thereby forming one-dimensional Ni nanorods.

Thereafter, a material characteristic analysis is performed on the one-dimensional metallic nanostructure formed by the method of the present invention. The following analysis is performed by the use of the one-dimensional Ni nanorods formed in the above experimental example.

Scanning Electron Microscope (SEM) Analysis.

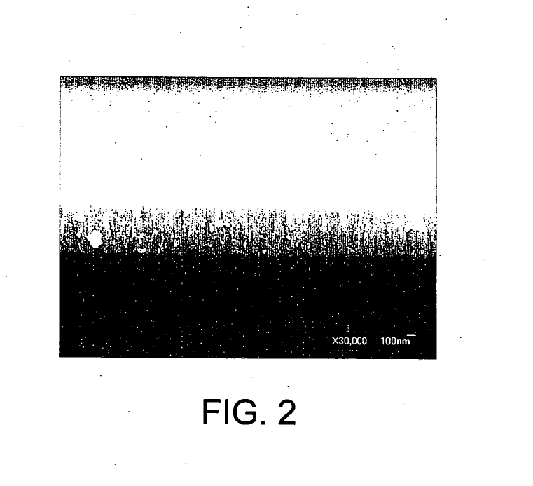

FIG. 2 is an SEM photograph of the oxide mixing layer (NiO-doped YSZ).

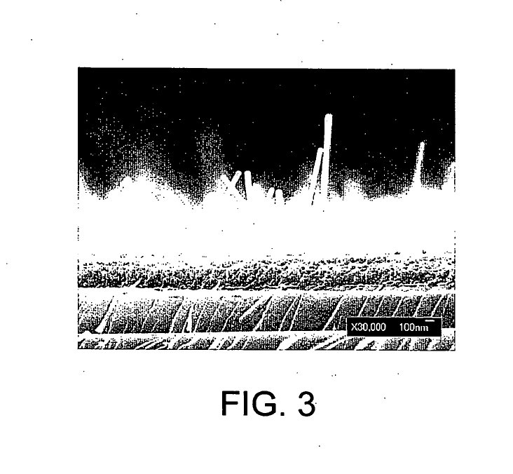

FIG. 3 is an SEM photograph of the mixing layer after the annealing process with H₂.

It can be seen from FIG. 2 that the SEM photograph of NiO-doped YSZ shows a flat surface of the mixing film. The SEM photograph of FIG. 3 clearly shows that the microstructure of the surface presents the one-dimensional nanorod morphology, and the formed one-dimensional Ni nanorods have a width of about 45-140 nm, and a length of about 230-1400 nm. It can be known from the analysis on the surface morphology of SEM that, the method of the present invention is easy and simple, and may indubitably form the one-dimensional metallic nanostructures.

In addition, a further research and analysis may be performed on the crystalline structure or atom orientation of the above one-dimensional metallic nanostructures with an X-ray diffraction and a transmission electron microscope.

X-Ray Diffraction (XRD) Analysis

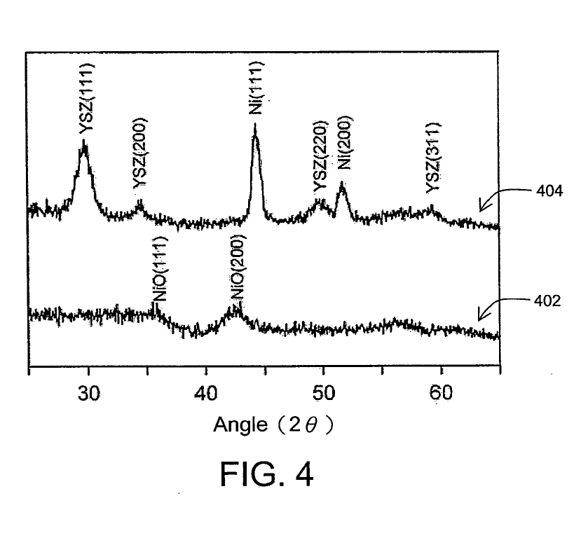

Referring to FIG. 4, an XRD spectrum of the oxide mixing layer (NiO-doped YSZ) and the mixing layer after the annealing process with H₂ is shown. The XRD spectrum of the oxide mixing layer (NiO-doped YSZ) is the spectrum marked by 402, and the XRD spectrum of the mixing layer of the formed one-dimensional Ni nanorods is the spectrum marked by 404. It can be clearly seen from FIG. 4 that Ni diffraction peak appears in the spectrum 404, i.e., one-dimensional metallic nanostructures may be formed by the method of the present invention. In addition, the graphic of the Ni diffraction peak is relatively sharp and narrow, indicating that the crystallinity is quite high.

Transmission Electron Microscope (TEM) Analysis

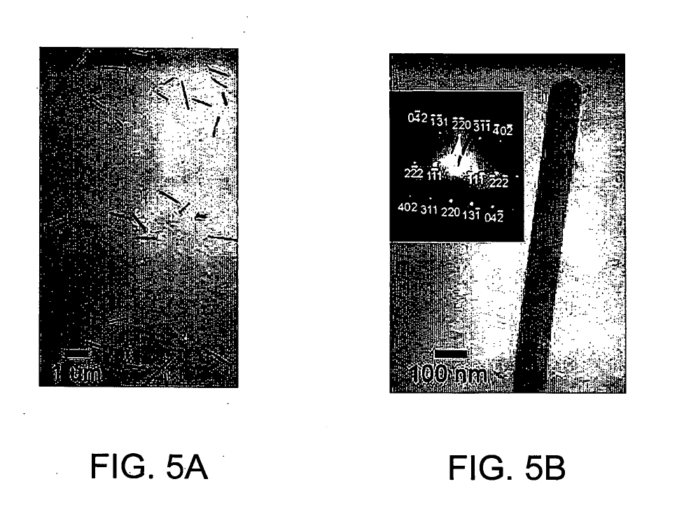

FIG. 5A is a TEM photograph of the one-dimensional metallic nanostructure obtained by performing the annealing process with H₂. FIG. 5B is an enlarged TEM photograph of FIG. 5A with an electron-diffraction spectrum inserted.

Likely, it can be known from the TEM analysis in FIG. 5A and FIG. 5B that, one-dimensional Ni nanorods can be formed by the method of the present invention, and the formed one-dimensional Ni nanorods have high crystallinity.

In view of above, the method of the present invention adopts a simple direct growth manner to form the one-dimensional metallic nanostructure, and the formed one-dimensional metallic nanostructure has high crystallinity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a one-dimensional metallic nanostructure, comprising:
forming a mixing layer comprising a first oxide and a second oxide, wherein the first oxide is a metallic oxide, and the first oxide and the second oxide are immiscible; and
introducing a reducing gas, and performing a thermal process on the mixing layer, so as to reduce a metal of the first oxide, thereby forming the one-dimensional metallic nanostructure on a surface of the mixing layer.

2. The method of fabricating a one-dimensional metallic nanostructure as claimed in claim 1, wherein the reducing gas comprises hydrogen (H₂).

3. The method of fabricating a one-dimensional metallic nanostructure as claimed in claim 1, wherein a process temperature of the thermal process is between 600° C. and 950° C.

4. The method of fabricating a one-dimensional metallic nanostructure as claimed in claim 1, wherein the thermal process comprises an annealing process.

5. The method of fabricating a one-dimensional metallic nanostructure as claimed in claim 1, wherein the first oxide comprises nickel oxide (NiO) or copper oxide (CuO).

6. The method of fabricating a one-dimensional metallic nanostructure as claimed in claim 1, wherein the second oxide comprises metallic oxide or ceramic oxide.

7. The method of fabricating a one-dimensional metallic nanostructure as claimed in claim 6, wherein the metallic oxide comprises zirconium oxide (ZrO₂), yttria-stabilized zirconia (YSZ) or cerium oxide doped yttria-stabilized zirconia (CeO₂-doped YSZ).

8. The method of fabricating a one-dimensional metallic nanostructure as claimed in claim 6, wherein the ceramic oxide comprises silica.

9. The method of fabricating a one-dimensional metallic nanostructure as claimed in claim 1, wherein the mixing layer is formed by a sputtering process or a deposition process.

10. The method of fabricating a one-dimensional metallic nanostructure as claimed in claim 1, wherein the one-dimensional metallic nanostructure comprises one-dimensional nanowires, one-dimensional nanorods, or one-dimensional nanocones.
